(19) United States
(12) Patent Application Publication
(10) Pub. No.: US 2022/0130651 A1
(43) Pub. Date: Apr. 28, 2022

(54) PROCESSING SYSTEM AND PROCESSING METHOD

(71) Applicant: Tokyo Electron Limited, Tokyo (JP)

(72) Inventors: Norihiko AMIKURA, Miyagi (JP); Makoto SAEGUSA, Miyagi (JP); Jun HIROSE, Miyagi (JP)

(73) Assignee: Tokyo Electron Limited, Tokyo (JP)

(21) Appl. No.: 17/507,956

(22) Filed: Oct. 22, 2021

(30) Foreign Application Priority Data
Oct. 23, 2020 (JP) 2020-178366

(51) Int. Cl. H01J 37/32

(52) U.S. Cl. CPC H01J 37/32935; H01J 37/32733; H01J 37/32862; H01J 37/32642; H01J 37/32697

(57) ABSTRACT

There is provided a system for processing a substrate under a depressurized environment. The system comprises: a processing chamber configured to perform desired processing on a substrate; a transfer chamber having a transfer mechanism configured to import or export the substrate into or from the processing chamber; and a controller configured to control a processing process in the processing chamber. The transfer mechanism comprises: a fork configured to hold the substrate on an upper surface; and a sensor provided in the fork and configured to measure an internal state of the processing chamber. The controller is configured to control the processing process in the processing chamber on the basis of the internal state of the processing chamber measured by the sensor.

### CROSS-REFERENCE TO RELATED APPLICATION

This application claims priority to Japanese Patent Application No. 2020-178366, filed on Oct. 23, 2020, the entire contents of which are incorporated herein by reference.

### TECHNICAL FIELD

The present disclosure relates to a system and method of processing a substrate.

### BACKGROUND

Japanese Patent Application Publication No. 2000-003905 discloses an etching apparatus including a ray spectroscopy monitor capable of monitoring the film thickness and film quality of reaction products deposited inside an etching chamber.

### SUMMARY

A technique according to the present disclosure measures the internal state of a plasma processing chamber using a sensor provided on a transfer fork and appropriately processes the substrate based on the measurement result.

In accordance with an aspect of the present disclosure, there is provided a system for processing a substrate under a depressurized environment. The system comprises: a processing chamber configured to perform desired processing on a substrate; a transfer chamber having a transfer mechanism configured to import or export the substrate into or from the processing chamber; and a controller configured to control a processing process in the processing chamber. The transfer mechanism comprises: a fork configured to hold the substrate on an upper surface; and a sensor provided in the fork and configured to measure an internal state of the processing chamber. The controller is configured to control the processing process in the processing chamber on the basis of the internal state of the processing chamber measured by the sensor.

### BRIEF DESCRIPTION OF THE DRAWINGS

FIG. 1 is a plan view showing a configuration example of a plasma processing system according to the present embodiment.

FIG. 2 is an explanatory diagram showing an installation example of a sensor according to the present embodiment.

FIG. 3 is a longitudinal sectional view showing a configuration example of a processing module according to the present embodiment.

FIG. 4 is a longitudinal sectional view showing another configuration example of the processing module according to the present embodiment.

FIG. 5 is an explanatory diagram showing an aspect of the measurement of an internal chamber environment by a sensor.

FIG. 6 is a longitudinal sectional view showing another configuration example of the processing module according to the present embodiment.

FIG. 7 is an explanatory diagram showing an aspect of the measurement of an internal chamber environment by a sensor.

FIG. 8 is an explanatory diagram showing another configuration example of a wafer transfer mechanism according to the present embodiment.

### DETAILED DESCRIPTION

In the semiconductor device manufacturing process, a processing gas is supplied to a semiconductor wafer (hereinafter, simply referred to as “wafer”), and various types of plasma processing such as etching processing, film formation processing, and diffusion processing are performed on a wafer. The plasma processing is generally performed inside a processing chamber of which the inside is adjustable to a reduced pressure atmosphere.

By the way, plasma processing requires a uniform processing result for each of a plurality of wafers that are continuously processed. However, as the plasma processing for the plurality of wafers is repeated, the internal environment of the processing chamber changes due to the consumption of members in the processing chamber and the adhesion of reaction by-products. Therefore, even if the processing is performed under the same conditions, uniform processing results may not be obtained. Thus, in order to obtain a uniform processing result in plasma processing, installing a member such as a sensor in the processing chamber for monitoring the internal state of the processing chamber and changing processing conditions depending on the internal environment of the processing chamber or improving the internal environment (cleaning and member replacement) is considered.

Japanese Patent Application Publication No. 2000-003905 discloses a plasma processing apparatus (an etching apparatus) provided with a ray spectroscopy monitor capable of monitoring the film thickness and film quality of reaction products deposited inside a processing chamber (an etching chamber). According to the etching apparatus described in Japanese Patent Application Publication No. 2000-003905, infrared light is emitted from a ray spectroscopy monitor installed outside the processing chamber toward two reflecting mirrors installed inside the processing chamber.

However, when a member such as a sensor is installed inside the processing chamber, like a reflecting mirror attached to the etching chamber in Japanese Patent Application Publication No. 2000-003905, the member may be degraded or damaged by being exposed to a plasma processing space.

Further, when a sensor is to be installed inside a processing chamber, it may be difficult to install a member such as a sensor due to the positional relationship with a structure provided inside the chamber. Furthermore, in order to monitor several environments (e.g., reaction by-products, potential, temperature, etc.) in the processing chamber, it is necessary to install a plurality of sensors, and in such a case, it may be more difficult to install the sensors. As described above, a conventional plasma processing apparatus has room for improvement to appropriately monitor the internal environment of a processing chamber.

A technique according to the present disclosure has been made in view of the above circumstances and measures the internal state of a plasma processing chamber using a sensor provided on a transfer fork and appropriately processes a substrate based on the measurement result. Hereinafter, a plasma processing system according to the present embodiment will be described with reference to the drawings. Also, in the present specification and the drawings, elements having substantially the same functional configurations are designated by the same reference numerals, and thus a detailed description thereof will be omitted.

<Plasma Processing System>

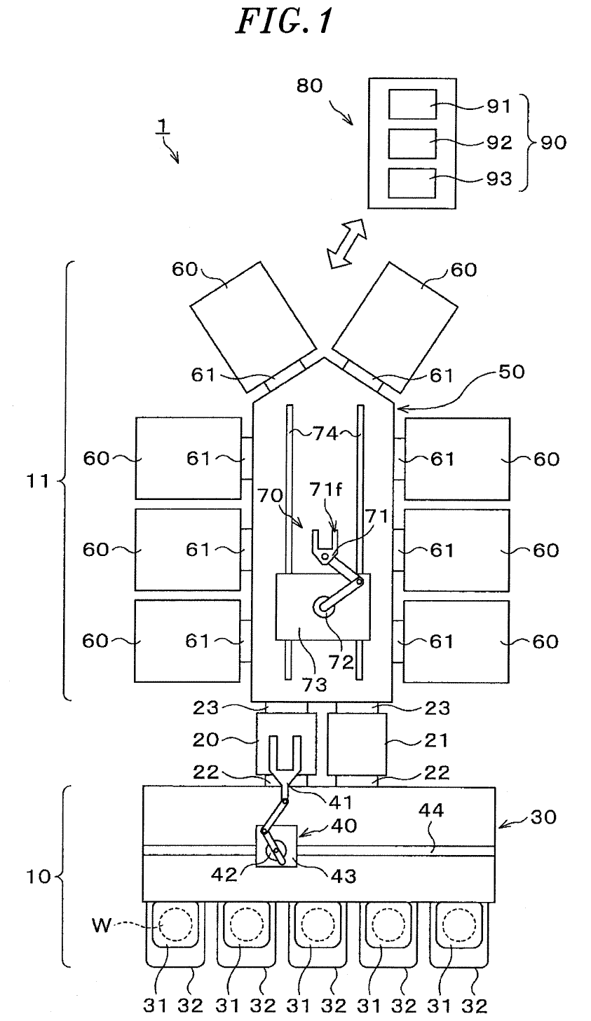

First, a plasma processing system according to the present embodiment will be described. FIG. 1 is a plan view schematically showing a configuration of a plasma processing system 1 according to the present embodiment. In the plasma processing system 1, a wafer W, which is a substrate, is subjected to plasma processing such as, for example, etching processing, film formation processing, and diffusion processing.

As shown in FIG. 1, the plasma processing system 1 has a configuration in which an atmospheric part 10 and a depressurizing part 11 are integrally connected through load lock modules 20 and 21. The atmospheric part 10 includes an atmospheric module that performs desired processing on a wafer W in an atmospheric pressure atmosphere. The depressurizing part 11 includes a depressurizing module that performs desired processing on a wafer W under a depressurized atmosphere.

The load lock modules 20 and 21 are provided to connect a loader module 30 of the atmospheric part 10, which will be described below, and a transfer module 50 of the depressurizing part 11, which will be described below, through a gate valve 22 and a gate valve 23, respectively. The load lock modules 20 and 21 are configured to temporarily hold the wafer W. Also, the load lock modules 20 and 21 are configured to switch the inside thereof between an atmospheric pressure atmosphere and a depressurized atmosphere (vacuum state).

The atmospheric part 10 has a loader module 30 provided with a wafer transfer mechanism 40, which will be described below, and a load port 32 having a front-opening unified pod (FOUP) 31 mounted to store a plurality of wafers W. Also, an orientation module (not shown) for adjusting the horizontal direction of the wafer W, a storage module (not shown) for storing a plurality of wafers W, and the like may be provided adjacent to the loader module 30.

The loader module 30 has a rectangular housing inside, and the inside of the housing is maintained in an atmospheric pressure atmosphere. A plurality of, e.g., five load ports 32 are arranged side by side on one side surface forming a long side of the housing of the loader module 30. The load lock modules 20 and 21 are arranged on another side surface forming a long side of the housing of the loader module 30.

A wafer transfer mechanism 40 for transferring the wafer

W is provided inside the loader module 30. The wafer transfer mechanism 40 has a transfer arm 41 that holds and moves the wafer W, a rotary table 42 that rotatably supports the transfer arm 41, and a rotary mounting table 43 on which the rotary table 42 is mounted. Further, a guide rail 44 extending in the longitudinal direction of the loader module 30 is provided inside the loader module 30. The rotary mounting table 43 is provided on the guide rail 44, and the wafer transfer mechanism 40 is configured to be movable along the guide rail 44.

The depressurizing part 11 has a transfer module 50 that internally transfers the wafer W and a processing module 60 that performs desired processing on the wafer W transferred from the transfer module 50. The inside of the transfer module 50 and the inside of the processing module 60 are maintained in a depressurized atmosphere. Also, in the present embodiment, a plurality of, e.g., eight, processing modules 60 are connected to one transfer module 50. Also, the number or arrangement of processing modules 60 is not limited to the present embodiment and may be arbitrarily set.

The transfer module 50 has a polygonal (pentagonal in the illustrated example) housing inside and is connected to the load lock modules 20 and 21 as described above. The transfer module 50 transfers a wafer W imported into the load lock module 20 to one processing module 60, performs desired processing, and then exports the wafer W to the atmospheric part 10 through the load lock module 21.

The processing module 60, as a processing chamber, performs plasma processing such as, for example, etching processing, film formation processing, and diffusion processing. As the processing module 60, a module that performs processing according to the purpose of processing the wafer may be arbitrarily selected. Also, the processing module 60 is connected to the transfer module 50 through a gate valve 61. Also, the configuration of the processing module 60 will be described below.

A wafer transfer mechanism 70 for transferring the wafer W is provided inside the transfer module 50 as the transfer chamber. The wafer transfer mechanism 70 has a transfer arm 71 that holds and moves the wafer W, a rotary table 72 that rotatably supports the transfer arm 71, and a rotary mounting table 73 on which the rotary table 72 is mounted. Further, a guide rail 74 extending in the longitudinal direction of the transfer module 50 is provided inside the transfer module 50. The rotary mounting table 73 is provided on the guide rail 74, and the wafer transfer mechanism 70 is configured to be movable along the guide rail 74.

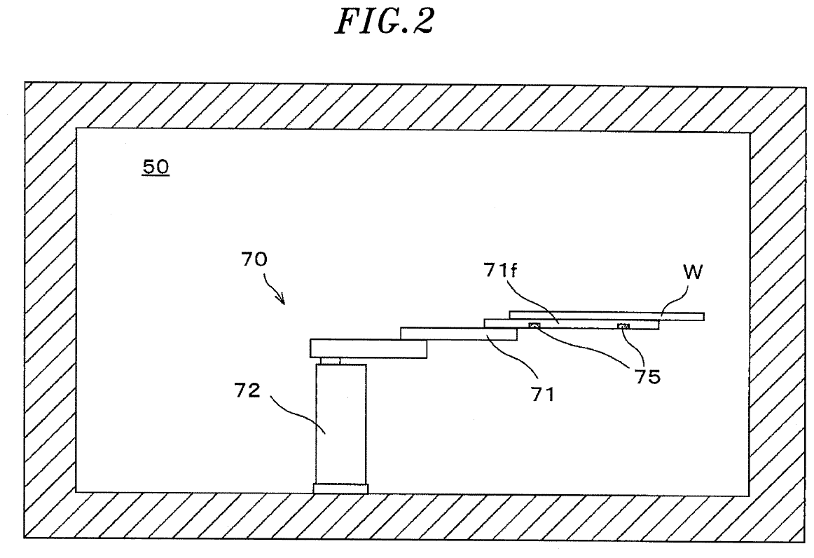

As shown in FIG. 1, the transfer arm 71 has a fork 71f that holds the wafer W at its tip. Further, as shown in FIG. 2, the fork 71f is provided with various sensors 75 for measuring the internal environment of the processing module 60. The sensor 75 monitors the internal environment (e.g., the surface potential or temperature of a wafer support part 110, the adhesion of reaction products (deposits), etc., which will be described below) of the processing module 60, for example, while the transfer arm 71 is moved into the processing module 60. Also, a method of monitoring the internal environment of the processing module 60 using the sensor 75 will be described in detail below.

The transfer module 50 receives the wafer W held by the load lock module 20 using the transfer arm 71 and transfers the wafer W to any processing module 60. Further, the transfer arm 71 holds the wafer W that has been subjected to the desired processing by the processing module 60 and exports the wafer W to the load lock module 21. Also, as described above, by moving the transfer arm 71 (the fork 71f) of the wafer transfer mechanism 70 into any processing module 60, the sensor 75 monitors the internal environment of the processing module 60.

Further, the plasma processing system 1 has a control device 80 as a controller. In an embodiment, the control device 80 executes computer-executable instructions that cause the plasma processing system 1 to perform several processes described in the present disclosure. The control device 80 may be configured to control each of the other elements of the plasma processing system 1 to perform several processes described herein. In an embodiment, a portion or the entirety of the control device 80 may be included in the other elements of the plasma processing system 1. The control device 80 may include, for example, a computer 90. The computer 90 includes, for example, a central processing unit (CPU) 91, a memory 92, a communication interface 93, etc. The CPU 91 may be configured to perform various control operations based on a program stored in the memory 92. The memory 92 may include a random-access memory (RAM), a read-only memory (ROM), a hard disk drive (HDD), a solid-state drive (SDD), or a combination thereof. The communication interface 93 may communicate with the other elements of the plasma processing system 1 via a communication line such as a local area network (LAN).

<Processing Module>

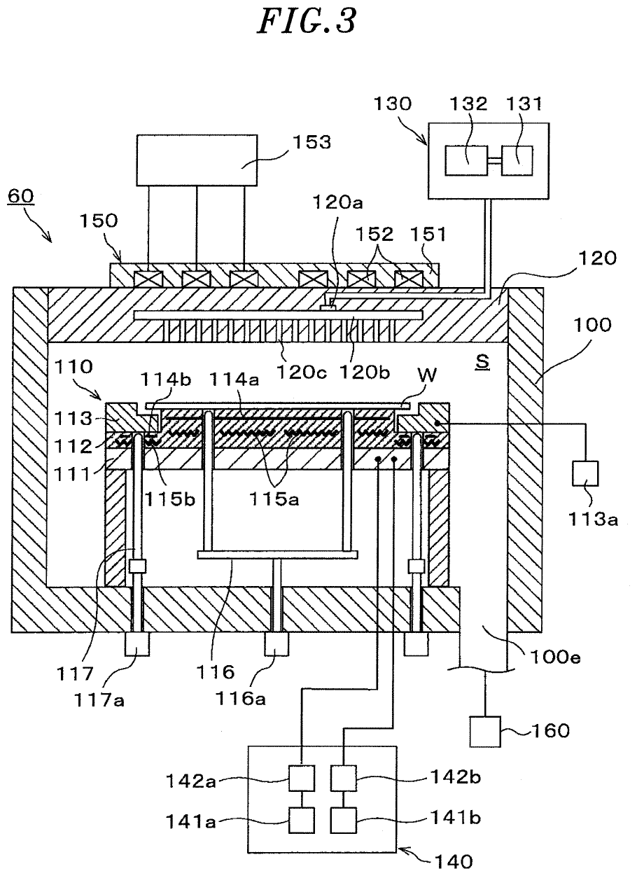

The plasma processing system 1 according to the present embodiment is configured as described above. The detailed configuration of the above-described processing module 60 will be described below. FIG. 3 is a longitudinal sectional view schematically showing the configuration of the processing module 60.

As shown in FIG. 3, the processing module 60 includes a chamber 100, a wafer support part 110, an upper electrode shower head 120, a gas supplier 130, a radio frequency (RF) power supply 140, an electromagnet 150, and an exhaust system 160.

The chamber 100 defines a processing space S in which plasma is generated. The chamber 100 is formed of, for example, aluminum. The chamber 100 is connected to ground potential.

The wafer support part 110 that supports the wafer W is accommodated in a lower region of the processing space S inside the chamber 100. The wafer support part 110 has a lower electrode 111, an electrostatic chuck 112, and an edge ring 113.

The lower electrode 111 is made of a conductive metal, e.g., aluminum, and has a substantial disk shape. A refrigerant flow path (not shown) is formed inside the lower electrode 111. Then, the electrostatic chuck 112, the edge ring 113, and the wafer W may be cooled to a desired temperature by circulating, in the refrigerant flow path, a refrigerant such as cooling water from a chiller unit (not shown) provided outside the chamber 100.

The electrostatic chuck 112 is provided on the lower electrode 111. The electrostatic chuck 112 is a member configured to attract and hold the wafer W and the edge ring 113 by electrostatic forces. In the electrostatic chuck 112, an upper surface of a central portion is higher than an upper surface of a peripheral portion.

The upper surface of the central portion of the electrostatic chuck 112 serves as a substrate holding area on which the wafer W is held, and the upper surface of the peripheral portion of the electrostatic chuck 112 serves as an edge ring holding area on which the edge ring 113 is held.

A first electrode 114a for attracting and holding the wafer W is provided inside the center portion of the electrostatic chuck 112. A second electrode 114b for attracting and holding the edge ring 113 is provided inside the peripheral portion of the electrostatic chuck 112. The electrostatic chuck 112 has a configuration in which the first electrode 114a and the second electrode 114b are inserted into an insulator made of an insulating material.

A direct current (DC) voltage is applied from a DC power source (not shown) to the first electrode 114a. An electrostatic force generated by the DC Voltage causes the wafer W to be attracted and held on the upper surface of the central portion of the electrostatic chuck 112. Similarly, a DC voltage is applied from a DC power source (not shown) to the second electrode 114b. An electrostatic force generated by the DC voltage causes the edge ring 113 to be attracted and held on the upper surface of the peripheral portion of the electrostatic chuck 112.

Also, the configurations of the first electrode 114a and the second electrode 114b can be arbitrarily selected and, for example, may be of a unipolar type or a bipolar type. Also, according to the present embodiment, the central portion of the electrostatic chuck 112 provided with the first electrode 114a and the peripheral portion of the electrostatic chuck 112 provided with the second electrode 114b are integrated with each other but may be separated from each other.

Also, a first heater 115a and a second heater 115b, which are heating elements, are provided below the first electrode 114a and the second electrode 114b, respectively. A heater power supply (not shown) is connected to the first heater 115a and the second heater 115b, and by applying a voltage from the heater power supply, the wafer support part 110, the wafer W mounted on the wafer support part 110, and the edge ring 113 are heated to a desired temperature.

Further, in the present embodiment, as shown in FIG. 3, a plurality of first heaters 115a are provided to extend inside the electrostatic chuck 112. The plurality of first heaters 115a are configured to be independently controllable and are configured such that the temperature of the electrostatic chuck 112 (the wafer W) can be adjusted independently for each of a plurality of temperature adjustment regions. In addition, the number and shape of the temperature adjustment regions on which temperature adjustment is performed independently by the plurality of first heaters 115a may be arbitrarily determined.

The edge ring 113 is an annular member arranged to surround the wafer W supported on the upper surface of the central portion of the electrostatic chuck 112 (wafer holding area), and a DC voltage is applied from the DC power supply 113a. The edge ring 113 is provided so as to improve the uniformity of plasma processing. Therefore, the edge ring 113 is made of a material appropriately selected according to the plasma processing and may be made of, e.g., Si or SiC.

The DC power supply 113a is a power supply that applies a negative DC voltage for plasma control to the edge ring 113. The DC power supply 113a is a variable DC power supply, and the magnitude of the DC voltage may be adjusted. Also, the DC power supply 113a is configured such that a voltage waveform applied to the edge ring 113 can be switched between a pulse wave and a continuous wave (CW).

Also, a first lifter pin 116 and a second lifter pin 117 are provided below the lower electrode 111 of the wafer support part 110.

The first lifter pin 116 is provided so as to be inserted into a through-hole extending from the upper surface of the central portion of the electrostatic chuck 112 to the bottom surface of the lower electrode 111. The first lifter pin 116 is formed of, for example, ceramic. Three or more first lifter pins 116 are provided along the circumferential direction of the electrostatic chuck 112 at intervals from one another. Also, the tip of the first lifter pin 116 is configured to be retractable from the upper surface of the central portion of the electrostatic chuck 112 by the operation of the lifter 116a provided with a driving part (not shown). Thus, the wafer W supported on the upper surface of the central portion of the electrostatic chuck 112 is configured to be lifted and lowered.

The second lifter pin 117 is provided so as to be inserted into a through-hole extending from the upper surface of the peripheral portion of the electrostatic chuck 112 to the bottom surface of the lower electrode 111. The second lifter pin 117 is formed of, for example, alumina, quartz, steel use stainless (SUS), or the like. Three or more second lifter pins 117 are provided along the circumferential direction of the electrostatic chuck 112 at intervals from one another. Also, the tip of the second lifter pin 117 is configured to be retractable from the upper surface of the peripheral portion of the electrostatic chuck 112 by the operation of the lifter 117a provided with the driving part (not shown). Thus, the edge ring 113 supported on the upper surface of the peripheral portion of the electrostatic chuck 112 is configured to be lifted and lowered.

Further, in the wafer support part 110, a gas flow path (not shown) for supplying a heat transfer gas (backside gas) such as helium gas is formed on the rear surface of the wafer W supported on the upper surface of the electrostatic chuck 112. A gas supply source (not shown) is connected to the gas flow path, and the heat transfer gas from the gas supply source can control the wafer W supported by the electrostatic chuck 112 to a desired temperature.

An upper electrode shower head 120 is provided above the wafer support part 110 to face the wafer support part 110 and may function as a portion of the ceiling of the chamber 100. The upper electrode shower head 120 is configured to supply one or more processing gases from the gas supplier 130 to the processing space S. In an embodiment, the upper electrode shower head 120 has a gas inlet 120a, a gas diffusion chamber 120b, and a plurality of gas outlets 120c. The gas inlet 120a communicates fluidly with the gas supplier 130 and the gas diffusion chamber 120b. The plurality of gas outlets 120c communicate fluidly with the gas diffusion chamber 120b and the processing space S. In one embodiment, the upper electrode shower head 120 is configured to supply one or more processing gases from the gas inlet 120a to the processing space S through the gas diffusion chamber 120b and the plurality of gas outlets 120c.

The gas supplier 130 may include one or more gas sources 131 and one or more flow controllers 132. In an embodiment, the gas supplier 130 is configured to supply one or more processing gases to the gas inlet 120a from corresponding gas sources 131 to corresponding flow controller 132. Each flow controller 132 may be, for example, a mass flow controller or a pressure-controlled flow controller. Also, the gas supplier 130 may include one or more flow modulation devices configured to modulate or pulse the flow of one or more processing gases.

The RF power supply 140 transmits RF power, for example, one or more RF signals, to one or more electrodes, such as the lower electrode 111, the upper electrode shower head 120, or both of the lower electrode 111 and the upper electrode shower head 120. As a result, plasma is generated from one or more processing gases supplied to the processing space S. Thus, the RF power supply 140 may function as at least a portion of a plasma generator configured to generate plasma from one or more processing gases in the chamber 100. In one embodiment, the RF power supply 140 includes two RF generators 141a and 141b and two matching circuits 142a and 142b. In one embodiment, the RF power supply 140 is configured to supply a first RF signal from the first RF generator 141a to the lower electrode 111 through the first matching circuit 142a. For example, the first RF signal may have a frequency in the range of 27 MHz to 100 MHz.

Also, in an embodiment, the RF power supply 140 is configured to supply a second RF signal from the second RF generator 141b to the lower electrode 111 through the second matching circuit 142b. For example, the second RF signal may have a frequency in the range of 400 kHz to 13.56 MHz. Instead of the second RF generator 141b, a DC pulse generator may be used.

Further, although not shown, other embodiments can be considered in the present disclosure. For example, in an alternative embodiment, the RF power supply 140 may be configured to supply a first RF signal from an RF generator to the lower electrode 111, supply a second RF signal from another RF generation unit to the lower electrode 111, and supply a third RF signal from the still another RF generation unit to the lower electrode 111. In addition, in another alternative embodiment, a DC voltage may be applied to the upper electrode shower head 120.

Furthermore, in several embodiments, the amplitude of one or more RF signals (i.e., the first RF signal, the second

RF signal, etc.) may be pulsed or modulated. Amplitude modulation may include pulsing the amplitude of an RF signal between on- and off-states or between two or more different on-states.

An electromagnet 150 is provided above the upper electrode shower head 120. The electromagnet 150 has a core member 151, a plurality of coils 152, and an excitation circuit 153 electrically connected to the coils 152. Then, by supplying a current from the excitation circuit 153 to at least one coil 152, a magnetic field for uniformly controlling the plasma formed inside the processing space S may be generated in the electromagnet 150.

An exhaust system 160 may be connected to, for example, an exhaust port 100e provided at the bottom of the chamber 100. The exhaust system 160 may include a pressure valve and a vacuum pump. The vacuum pump may include a turbo molecular pump, a roughing vacuum pump, or a combination thereof.

Although several exemplary embodiments have been described above, various additions, omissions, substitutions, and changes may be made without being limited to the above-mentioned exemplary embodiments. Also, it is possible to combine elements in different embodiments to form other embodiments.

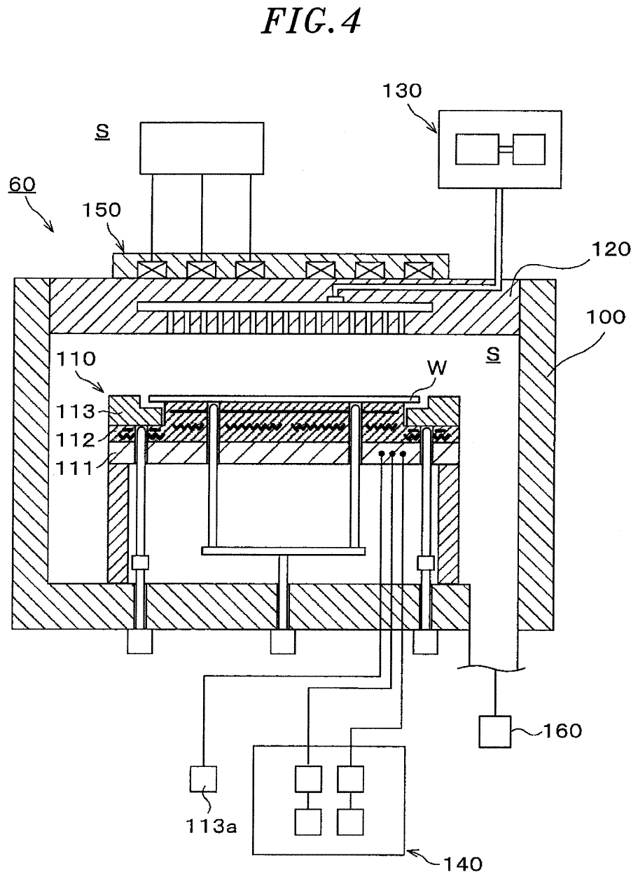

For example, in the above embodiment, the DC power supply 113a is connected to the edge ring 113 independently, but as shown in FIG. 4, the DC power supply 113a may be connected to the edge ring 113 via the lower electrode 111. Further, for example, instead of the DC power supply 113a, the RF power supply 140 connected to the lower electrode 111 may be branched and connected to the edge ring 113.

<Wafer Processing Method>

The processing module 60 according to the present embodiment is configured as described above. The plasma processing system 1 and wafer processing performed by using the processing module 60 will be described below.

First, a FOUP 31 containing a plurality of wafers W is mounted on a load port 32, and the wafer W is taken out of the FOUP 31 by the wafer transfer mechanism 40. Subsequently, the gate valve 22 of the load lock module 20 is opened, and the wafer W is imported into the load lock module 20 by the wafer transfer mechanism 40.

In the load lock module 20, the gate valve 22 is closed to seal the inside of the load lock module 20, and then the inside of the load lock module 20 is depressurized to a desired vacuum level. When the inside of the load lock module 20 is depressurized, the gate valve 23 is then opened, and the inside of the load lock module 20 and the inside of a transfer module 50 are communicated with each other.

When the gate valve 23 is opened, the wafer W in the load lock module 20 is transferred to the transfer module 50 by a wafer transfer mechanism 70, and the gate valve 23 is closed. Subsequently, a gate valve 61 of one processing module 60 is opened, and the wafer W is imported into the processing module 60 by the wafer transfer mechanism 70. When the wafer W is imported into the processing module 60, the gate valve 61 is closed, and the inside of the chamber 100 of the processing module 60 is sealed.

In the processing module 60, first, the wafer W is mounted on the electrostatic chuck 112 by raising and lowering the first lifter pin 116. Then, by applying a DC voltage to an electrode of the electrostatic chuck 112, the wafer W is electrostatically attracted and held by the electrostatic chuck 112 by electrostatic force. Further, after the wafer W is imported, the inside of the chamber 100 is depressurized to a desired vacuum level by the exhaust system 160.

Subsequently, a processing gas is supplied from the gas supplier 130 to the processing space S through the upper electrode shower head 120. Further, the RF power supply 140 supplies high-frequency power HF for plasma generation to the lower electrode 111 and excites the processing gas to generate plasma. At this time, the RF power supply 140 may supply high-frequency power LF for ion attraction. Also, at this time, the RF power supply 140 may supply a current to a coil 152 of the electromagnet 150 to generate a magnetic field inside the processing space S, thereby uniformly controlling plasma formed inside the processing space S. Then, desired plasma processing is performed on the wafer W by the action of the generated plasma.

Also, during the plasma processing, the temperatures of the wafer W and the edge ring 113 attracted and held by the electrostatic chuck 112 are adjusted by the temperature control module (the first heater 115a, the second heater 115b, and refrigerant circulating in the refrigerant flow path). At this time, in order to efficiently transfer heat to the wafer W, a heat transfer gas such as He gas or Ar gas is supplied toward the rear surface of the wafer W attracted onto the upper surface of the electrostatic chuck 112.

When the plasma processing is completed, first, the supply of the high-frequency power HF from the RF power supply 140 and the supply of the processing gas by the gas supplier 130 are stopped. Also, when the high-frequency power LF is supplied during the plasma processing, the supply of the high-frequency power LF is also stopped. Furthermore, the supply of the current to the coil 152 of the electromagnet 150 is also stopped. Next, the supply of the heat transfer gas to the rear surface of the wafer W is stopped, and the attraction and holding of the wafer W by the electrostatic chuck 112 is stopped.

Then, the wafer W is raised by the first lifter pin 116, and the wafer W is detached from the electrostatic chuck 112. At the time of this detachment, antistatic processing may be performed on the wafer W. Subsequently, the gate valve 61 is opened, and the wafer W is carried out of the processing module 60 by the wafer transfer mechanism 70. When the wafer W is carried out of the processing module 60, the gate valve 61 is closed.

Subsequently, the gate valve 23 of the load lock module 21 is opened, and the wafer W is imported into the load lock module 21 by the wafer transfer mechanism 70. In the load lock module 21, the gate valve 23 is closed to seal the inside of the load lock module 21, and then the inside of the load lock module 21 is opened to the atmosphere. When the inside of the load lock module 21 is opened to the atmosphere, the gate valve 22 is then opened, and the inside of the load lock module 21 and the inside of a loader module 30 are communicated with each other.

When the gate valve 22 is opened, the wafer W in the load lock module 21 is transferred to the loader module 30 by the wafer transfer mechanism 40, and the gate valve 22 is closed. Then, the wafer W is returned to and accommodated in the FOUP 31 mounted on the load port 32 by the wafer transfer mechanism 40. Then, the same processing is continuously performed on a plurality of wafers W contained in the FOUP 31, and when the processing for all the wafers W is completed, the series of wafer processing on the plasma processing system 1 is completed.

In the wafer processing in the plasma processing system 1, prior to the plasma processing on the wafer W in the processing module 60, dry cleaning may be performed to remove a reaction product (deposit) adhering to the inside of the chamber 100 of the corresponding processing module 60. That is, the deposit generated and attached by the plasma processing on one wafer W may be removed prior to the start of the plasma processing on the next wafer W. As a result, the adhesion to the next wafer W due to peeling and dropping of the deposit during the plasma processing is suppressed, and the plasma processing may be appropriately performed on the next wafer W.

Here, when the plasma processing is performed by using the processing module 60, it is required that the processing results for a plurality of wafers W that are continuously processed are uniform, that is, that the quality of a semiconductor device as a product is uniform. However, as described above, when plasma processing is continuously performed in one processing module 60, the internal environment of the chamber 100 changes due to the consumption of members, the adhesion of reaction by-products (depots), and the like, and thus there is a possibility that a uniform processing result cannot be obtained for the plurality of wafers W.

Therefore, in the plasma processing system 1 according to the present embodiment, as described above, the sensor 75 is provided on the transfer arm 71 that enters the inside of the processing module 60 when the wafer W is imported into and exported from the processing module 60. Then, the internal environment of the chamber 100 of the processing module 60 is measured by the sensor 75, and the measurement result is fed back to the processing process of the wafer W.

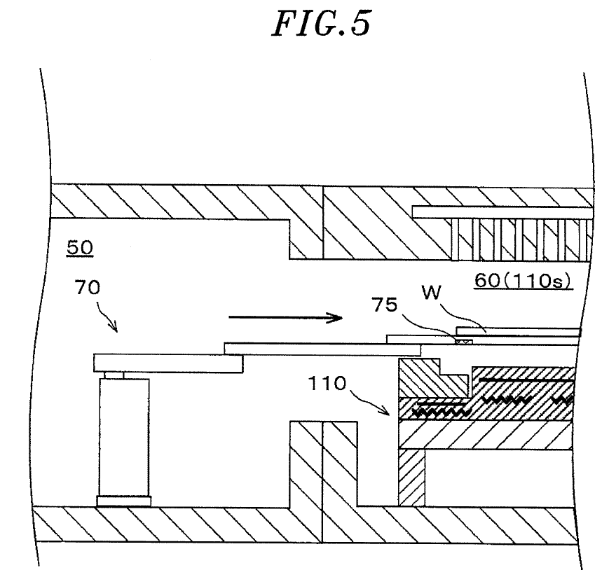

Specifically, as shown in FIG. 5, the transfer arm 71 of the wafer transfer mechanism 70 is moved into the chamber 100, and in this state, the internal environment of the chamber 100 is measured with a sensor 75 mounted on a fork 71f of the transfer arm 71. The timing of measuring the internal environment of the chamber 100 by the sensor 75 may be arbitrarily determined. For example, as described above, the measurement may be performed when the wafer W is imported into or exported from the processing module 60 or independently of when the wafer W is imported or exported. In other words, the internal environment of the chamber 100 may be measured while the wafer W is held on the transfer arm 71 or the internal environment of the chamber 100 may be measured while the wafer W is not held on the transfer arm 71.

<Measurement of Internal Environment and Feedback Control Method>

The “internal environment” of the chamber 100 measured by the sensor 75 and an example of the feedback control method performed based on the measurement result will be described below. Also, in the following description, among wafers W that are continuously processed in the processing module 60, a wafer W that is subject to plasma processing first may be simply referred to as “preceding wafer W” and a wafer W that is processed after the preceding wafer W may be referred to as “subsequent wafer W.”

(1) Surface Potential of Electrostatic Chuck 112

The surface potential of the electrostatic chuck 112 when the subsequent wafer W is attracted and held may be changed from the surface potential when the preceding wafer W is attracted and held, for example, due to the influence of residual charges during plasma processing of the preceding wafer W. When the surface potentials upon attraction and holding are different as described above, the attractive force of the preceding wafer W and the attractive force of the subsequent wafer W by the electrostatic chuck 112 are changed. As a result, the amount of heat transferred from the electrostatic chuck 112 to the wafer W during plasma processing is changed, that is, the temperature of the wafer W during plasma processing is changed. Thus, the plasma processing results of the preceding wafer W and the subsequent wafer W may not be the same.

Therefore, in the present embodiment, a potential sensor for detecting the surface potential of the electrostatic chuck 112 as the sensor 75 may be employed on the lower surface of the fork 71f which is a surface facing the electrostatic chuck 112. In such a case, the amount of DC voltage applied from the DC power supply (not shown) to a first electrode 114a may be controlled so that the surface potential is kept constant when the preceding wafer W and the subsequent wafer W are attracted and held.

Specifically, for example, when the wafer W is imported into the processing module 60, the surface potential of the electrostatic chuck 112 is measured by the sensor (potential sensor) 75 prior to the attraction and holding of the wafer W by the electrostatic chuck 112. Then, by reflecting the difference between the measured surface potential and the predetermined reference surface potential in the attractive potential due to the electrostatic chuck 112, the surface potential is controlled to be constant when the preceding wafer W and the subsequent wafer W are attracted and held.

As the above-mentioned “reference surface potential,” for example, the measurement result when the preceding wafer W is imported may be used, or a value arbitrarily set when the processing module 60 is set up may be used.

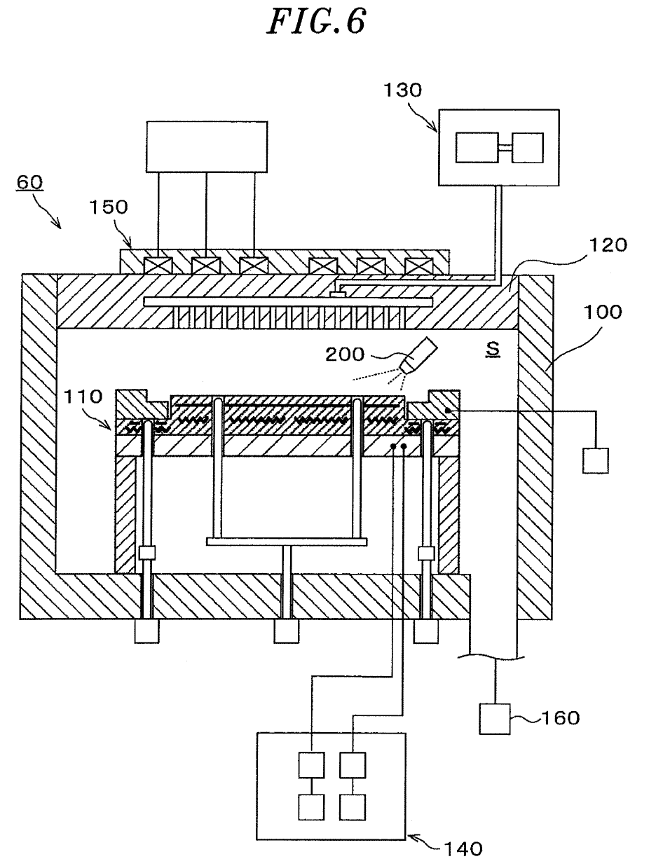

Also, the case where the amount of DC voltage applied from the DC power supply (not shown) is controlled based on the measurement result of the sensor (potential sensor) 75 has been described above as an example, but the method of controlling the surface potential is not limited thereto. For example, as shown in FIG. 6, an ionizer 200 for supplying an ionized gas toward the upper surface of the electrostatic chuck 112 is provided, and antistatic processing may be performed on the upper surface of the electrostatic chuck 112 on the basis of the measurement result of the sensor (potential sensor) 75.

(2) Surface Temperature of Electrostatic Chuck 112

The surface temperature of the electrostatic chuck 112 when the subsequent wafer W is attracted and held may be changed from the surface temperature when the preceding wafer W is attracted and held, for example, due to the influence of a change in the atmospheric temperature during plasma processing, a change in the amount of heat transferred from the electrostatic chuck 112 to the wafer, etc. When the surface temperatures upon attraction and holding are different as described above, the plasma processing results of the preceding wafer W and the subsequent wafer W may not be the same.

Therefore, in the present embodiment, a temperature sensor for detecting the surface temperature of the electrostatic chuck 112 as the sensor 75 may be employed on the lower surface of the fork 71f which is a surface facing the electrostatic chuck 112. In such a case, the amount of voltage applied from a heater power supply (not shown) to a first heater 115a may be controlled so that the surface temperature is kept constant when the preceding wafer W and the subsequent wafer W are attracted and held.

Specifically, for example, when the wafer W is imported into the processing module 60, the surface temperature of the electrostatic chuck 112 is measured by the sensor (temperature sensor) 75 prior to the attraction and holding of the wafer W by the electrostatic chuck 112. Then, by reflecting the difference between the measured surface temperature and the predetermined reference surface temperature in the voltage applied by the heater power source (not shown), the surface temperature is controlled to be constant when the preceding wafer W and the subsequent wafer W are attracted.

As the above-mentioned “reference surface temperature,” for example, the measurement result when the preceding wafer W is imported may be used, or a value arbitrarily set when the processing module 60 is set up may be used.

Also, in the processing module 60 according to the present embodiment, as described above, a plurality of first heaters 115a are extended and installed inside the electrostatic chuck 112 so that the surface temperature of the electrostatic chuck 112 can be adjusted for each temperature control region that is arbitrarily set. Therefore, when a temperature sensor is used as the sensor 75, it is preferable that surface temperatures be measured at a plurality of points on the upper surface of the electrostatic chuck 112 by the sensor (temperature sensor) 75 and controlled for each temperature control region. In such a case, for example, a plurality of sensors (temperature sensors) 75 may be installed on the fork 71f of the transfer arm 71. Also, for example, specifically, the movement operation of the transfer arm 71 may be controlled by a controller 80 rather than the fork 71f of the transfer arm 71 so that the sensor 75 is arbitrarily moved above the electrostatic chuck 112.

Also, the case where the amount of voltage applied from the heater power supply (not shown) is controlled based on the measurement result of the sensor (temperature sensor) 75 has been described above as an example, but the method of controlling the surface temperature is not limited thereto. For example, instead of controlling the amount of voltage applied from the heater power supply, the temperature of the first heater 115a may be controlled by variably configuring a process start time for the wafer W in the processing module 60, that is, by changing when a voltage is applied from the heater power supply.

(3) Deposit Attached to Inside of Chamber 100

During plasma processing on the wafer W in the processing module 60, a reaction product (depot) is generated and adheres to, for example, the wall surface, the wafer support part 110, and the like of the chamber 100. Here, when plasma processing is performed on the wafer W while an excessive amount of deposits adhere to the inside of the chamber 100, the deposits adhering to the wall surface or the like of the chamber 100 may be peeled off or scattered during the plasma processing. As a result, the deposits that have been peeled off or scattered adhere to the wafer W being processed, and thus, the plasma processing results of the preceding wafer W and the subsequent wafer W may not be the same. Further, since the amount of generation (the amount of adhesion) or the positions of adhesion of deposits during plasma processing are different depending on the conditions for the plasma processing (e.g., a processing gas flow rate, a processing temperature, etc.), it is required to appropriately detect the positions or amount of adhesion of deposits inside the chamber 100.

Therefore, in the present embodiment, an imaging sensor (e.g., a CCD camera) for detecting the wafer support part 110 or the wall surface of the chamber 100 as the sensor 75 may be employed in the fork 71f. In such a case, the conditions for plasma processing of the subsequent wafer W (e.g., the internal pressure of the chamber 100, the flow rate of the processing gas, the power of the RF signal, etc.) may be controlled so that the adhering deposits are not peeled off or scattered during the plasma processing of the subsequent wafer W.

Specifically, for example, when the wafer W is exported from the processing module 60, the sensor (imaging sensor) 75 images the wall surface of the chamber 100 and the surface of the wafer support part 110. Then, the conditions for plasma processing on the subsequent wafer W are optimized based on the amount of change between the adhesion state of deposits inside the chamber 100 obtained by imaging and a predetermined reference deposit adhesion state, and thus deposit peeling and scattering are suppressed when plasma processing is performed on the subsequent wafer W.

As the above-mentioned “reference deposit adhesion state,” for example, the imaging result when the preceding wafer W is exported may be used, or a state arbitrarily set when the processing module 60 is set up may be used.

Also, a surface imaged by the sensor (imaging sensor) 75 may be appropriately determined according to, for example, the conditions for plasma processing on the wafer W and may be selected from among a side wall surface or a ceiling surface inside the chamber 100, an upper surface or a side surface of the wafer support part 110, and the like. For example, when surfaces to which deposits are likely to adhere are known due to the conditions for plasma processing, only one or more of the surfaces to which deposits are likely to adhere may be imaged. At this time, when the ceiling surface of the chamber 100 is imaged, it is preferable that the sensor (imaging sensor) 75 be provided at a position that does not interfere with the wafer W held on the transfer arm 71.

Further, the number of sensors (imaging sensors) 75 installed on the fork 71f is not particularly limited, and a plurality of sensors (imaging sensors) 75 may be installed, or one sensor (imaging sensor) 75 may be configured to image a plurality of surfaces in the chamber 100.

Also, in the above description, the conditions for plasma processing on the subsequent wafer W are changed according to the amount of change from a reference adhesion state, but for example, when the amount of adhesion of deposits inside the chamber 100 is large, dry cleaning processing, that is, deposit removal processing, may be performed prior to the plasma processing on the subsequent wafer W. In such a case, the conditions for the dry cleaning processing (e.g., the flow rate of the cleaning gas, the cleaning time, etc.) may be adjusted according to the amount of adhesion of depots.

Also, the case where the inside of the chamber 100 is imaged when the preceding wafer W is exported from the processing module 60 has been described above as an example, but deposits may be imaged after the transfer arm 71 is input into the chamber 100 independently of the exportation of the wafer W.

(4) Height Position of Edge Ring 113

The edge ring 113 provided inside the chamber 100 is a consumable component that is consumed by plasma processing. The height position of the upper surface of the edge ring 113 may be lowered by repeating plasma processing on a plurality of wafers W. When the height position of the upper surface of the edge ring 113 is changed, the position of the sheath end formed inside the processing space S is changed during plasma processing. As a result, the plasma processing result for the preceding wafer W and the plasma processing result for the subsequent wafer W may not be the same.

Therefore, in the present embodiment, a distance sensor for detecting the height position of the upper surface of the edge ring 113 as the sensor 75 may be employed on the lower surface of the fork 71f which is a surface facing the upper surface of the edge ring 113. In such a case, the raising and lowering of the second lifter pin 117 may be controlled so that the height position of the upper surface of the edge ring 113 is kept constant during the plasma processing of the preceding wafer W and the subsequent wafer W. In other words, the height position of the edge ring 113 is adjusted by driving the second lifter pin 117, thereby performing control such that the sheath end position is not changed during the plasma processing.

Specifically, for example, the height position of the upper surface of the edge ring 113 is measured by the sensor (distance sensor) 75 when the wafer W is imported into the processing module 60. Then, prior to the plasma processing on the wafer W, the second lifter pin 117 is raised or lowered based on the difference between the measured height position of the upper surface and a predetermined reference upper-surface height position, and thus the height position of the upper surface of the edge ring 113 is controlled to be constant during plasma processing on the preceding wafer W and the subsequent wafer W.

Also, the total amount of consumption of the edge ring 113, that is, the total amount of raising or lowering of the second lifter pin 117, is recorded in the control device 80, and when the total amount of consumption (the total amount of raising or lowering) reaches a predetermined threshold value, an operator may be notified that the edge ring 113 needs to be replaced.

Also, when the sensor 75 detects a change in the height position of the upper surface of the edge ring 113, the amount of DC voltage applied from the DC power supply 113a to the edge ring 113 may be controlled according to the amount of consumption of the edge ring 113 instead of or in addition to the height position of the edge ring 113 being adjusted by driving the second lifter pin 117.

Specifically, even when the sheath of the edge ring 113 is lowered due to the consumption of the edge ring 113, it is possible to raise the sheath of the edge ring 113 by increasing the DC voltage applied to the corresponding edge ring 113. That is, thus, it possible to perform control such that the sheath end position is not changed during plasma processing, and also it is possible to uniformly control the plasma processing results of the preceding wafer W and the subsequent wafer W.

The measurement of the height position of the upper surface of the edge ring 113 by the sensor (distance sensor) 75 may be performed on an unconsumed edge ring 113. That is, the measurement may be performed on an edge ring 113 immediately after replacement. It may be considered that the replacement of the edge ring 113 is performed using the transfer arm 71 and the second lifter pin 117. In such a case, the edge ring 113 may not be mounted on the transfer arm 71 due to falling during transfer or may not be mounted on the edge ring holding area due to the failure of transmission to the second lifter pin 117. Therefore, in order to confirm that the edge ring 113 is mounted on the edge ring holding area, the height position of an upper surface of an unconsumed edge ring 113 may be measured.

Specifically, the sensor (distance sensor) 75 measures the height position of the upper surface of the edge ring 113 by moving and placing the transfer arm 71 above the edge ring 113. Since the edge ring 113 is not consumed, it is possible to estimate the height position of the upper surface. When the measured value and the estimated value of the height position of the upper surface of the edge ring 113 are the same, it may be determined that the edge ring 113 is mounted on the edge ring holding area. Also, when the measured value is equal to the height position of the edge ring holding area (the upper surface of the peripheral portion of the electrostatic chuck 112), it may be determined that the edge ring 113 is not mounted on the edge ring holding area. That is, the sensor (distance sensor) 75 may be used to detect the presence or absence of the edge ring 113.

(5) Holding Position of Edge Ring 113

Further, as the sensor 75, the distance sensor may detect whether or not the edge ring 113 after replacement is appropriately held with respect to the peripheral portion of the electrostatic chuck 112.

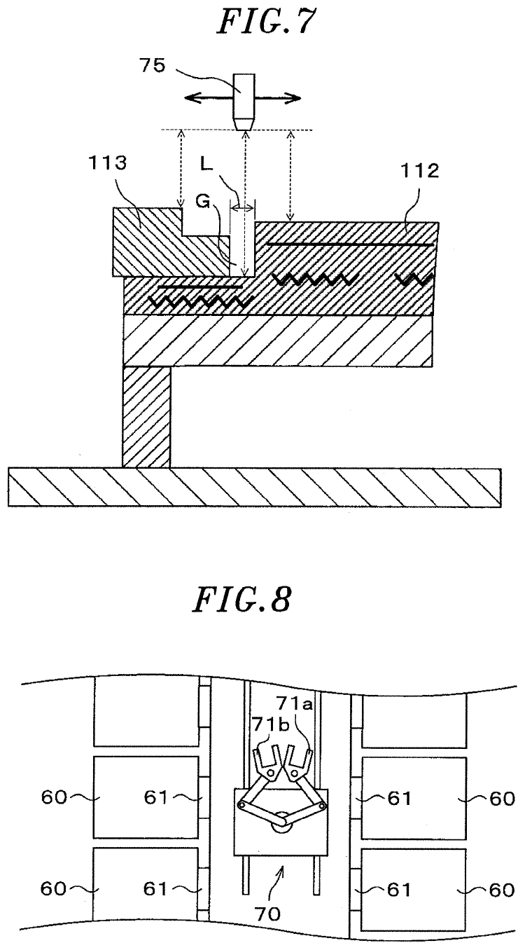

Specifically, for example, while measurement is being performed by the sensor (distance sensor) 75, the transfer arm 71 is moved from the outside to the inside above the electrostatic chuck 112 in the radial direction, and a horizontal gap between the edge ring 113 and the center portion of the electrostatic chuck 112 is detected. More specifically, as shown in FIG. 7, based on the height position of the upper surface of the edge ring 113, the height position of the central portion of the electrostatic chuck 112, and the difference in height position measured by a gap therebetween (gap G), a horizontal length L of the gap G is detected. Then, when the length L of the gap G is in the circumferential direction and thus is not constant, it is determined that the edge ring 113 is held eccentrically with respect to the electrostatic chuck 112, and for example, the operation of replacing the edge ring 113 (the operation of holding the electrostatic chuck 112) is repeated. While the edge ring 113 is eccentrically held, process conditions such as the flow rate or the proportion of a gas supplied to the processing space S, the temperature of the first heater 115a, etc. may be adjusted according to the eccentric position of the edge ring 113. For example, a first heater 115a in the vicinity of a position where the horizontal length L of the gap G is large and another first heater 115a in the vicinity of a position where the horizontal length L of the gap G is small may be controlled to be different temperatures.

Also, in the above description, the holding position of the edge ring 113 is detected by the distance sensor as the sensor 75, but the holding position of the edge ring 113 may be appropriately detected, for example, even when an imaging sensor (e.g., a CCD camera) is used as the sensor 75.

(6) Magnetic Field Formed Inside Chamber 100

In order to generate plasma uniformly inside the processing space S, a magnetic field generated by the electromagnet 150 may have magnetic force distribution changing due to the influence of the change in a geometrical positional relationship inside the chamber 100 due to, for example, the consumption of the electromagnet 150, the adhesion of depositions, or the like. When the magnetic force distribution of the magnetic field formed inside the processing space S is changed, the uniformity of the plasma generated inside the processing space is degraded, and as a result, the plasma processing results of the preceding wafer W and the subsequent wafer W may not be the same.

Therefore, in the present embodiment, a magnetic sensor for measuring a magnetic force distribution of a magnetic field formed inside the processing space S as the sensor 75 is employed on the upper surface of the fork 71f which is a surface facing the processing space S. In such a case, the amount of current supplied from the excitation circuit 153 to the coil 152 may be controlled so that the magnetic field (magnetic force distribution) is kept constant when plasma processing is performed on the preceding wafer W and the subsequent wafer W.

Specifically, for example, a magnetic field is generated inside the processing space S while there is no wafer W inside the processing module 60 (no wafer W is held by the transfer arm 71), and the magnetic force distribution of the generated magnetic field is measured by the sensor (magnetic sensor) 75. Then, when the measured time distribution is changed from a predetermined reference magnetic distribution (initial distribution), the current applied from the excitation circuit 153 to the coil 152 is adjusted.

Although several exemplary embodiments have been described above, various additions, omissions, substitutions, and changes may be made without being limited to the above-mentioned exemplary embodiments. Also, it is possible to combine elements in different embodiments to form other embodiments.

<Effects of Technique of Present Disclosure>

As described above, according to the plasma processing system 1 according to the present embodiment, the sensor 75 is provided to the transfer arm 71 of the wafer transfer mechanism 70, and more specifically, the fork 71f of the transfer arm 71. Thus, for example, when a wafer W is imported into or exported from the processing module 60 by the wafer transfer mechanism 70, it is possible to appropriately measure the internal environment of the chamber 100. Then, by adjusting (performing feedback control on) the plasma processing process for the wafer W on the basis of the measurement result of the sensor 75, it is possible to uniformly control the processing result of each wafer W continuously processed in the processing module 60.

Also, according to the present embodiment, the sensor 75 for measuring the internal environment of the chamber 100 is provided on the transfer arm 71 located outside the chamber 100 at the time of plasma processing, and thus it is possible to eliminate the influence caused by the plasma processing. That is, the sensor 75 is not consumed by plasma processing in the processing module 60, and thus it is possible to appropriately reduce the cost and time required for member replacement due to degradation and breakage.

Also, as described above, in the present embodiment, the case where a potential sensor, a magnetic sensor, or the like as the sensor 75 is independently provided on the fork 71f of the transfer arm 71 has been described as an example, but it will be appreciated that a plurality of types of sensors 75 may be combined and installed on the fork 71f of the transfer arm 71. That is, for example, one or more types of sensors 75 to be attached to the fork 71f may be selected according to the type and conditions of plasma processing performed inside the processing module 60, or for example, any type of sensor 75 that has been described above may be attached to the fork 71f.

Also, for example, when a plurality of transfer arms 71 are provided inside the transfer module 50, the type of sensor 75 to be attached may be selected for each of the plurality of transfer arms 71. At this time, for example, by selecting the type of sensor 75 for each of the roles of the plurality of transfer arms 71, it is possible to efficiently measure the internal environment and perform feedback control on the plasma processing process.

Specifically, for example, as shown in FIG. 8, the wafer transfer mechanism 70 may have a first transfer arm 71a that mainly imports a wafer W into the processing module 60 and a second transfer arm 71b that mainly exports a wafer W from the processing module 60. In such a case, for example, by providing the first transfer arm 71a with a potential sensor, a temperature sensor, and a distance sensor, it is possible to measure various internal environments when the wafer W is imported into the chamber 100. Also, for example, by providing the second transfer arm 71b with an imaging sensor, it is possible to detect the adhesion state of deposits inside the chamber 100 after plasma processing when the wafer W is exported.

As described above, the number and types of sensors 75 attached to the fork 71f of the transfer arm 71 and a combination thereof may be arbitrarily determined. Also, it will be appreciated that the type of sensor 75 is not limited to the above-mentioned potential sensor, temperature sensor, imaging sensor, distance sensor, and magnetic sensor, and another type of sensor 75 may be selected depending on the purpose.

Also, in the above embodiment, the case where the internal environment of the chamber 100 is measured by the sensor 75 and the plasma processing process is adjusted based on the measurement result has been described as an example. However, for example, the state of the wafer W held by the transfer arm 71 may be further measured in addition to the measurement of the internal environment of the chamber 100. Then, by adjusting the plasma processing process on the basis of both of the internal environment of the chamber 100 and the state of the held wafer W, it is possible to appropriately and uniformly control the processing result of the wafer W in the processing module 60.

Further, in the above embodiment, for example, the case where the internal environment is measured by the sensor 75 when the wafer is imported into or exported from the processing module 60 and the plasma processing process is adjusted based on the measurement result has been described as an example. However, the measurement timing of the internal environment by the sensor 75 is not limited thereto. For example, when periodic diagnosis or calibration is performed on the processing module 60, the internal environment may be measured by inputting the transfer arm 71 into the chamber 100.

Also, In the above embodiments, the case where the technique according to the present disclosure is applied to the plasma processing system 1 that performs plasma processing on a wafer W has been described as an example, but the technique according to the present disclosure is not limited to the plasma processing system 1 and may be applied to any system. That is, as long as a system can transfer a wafer W to a processing module using a wafer transfer mechanism having a fork, it is possible to appropriately and uniformly control processing results for a plurality of wafers W by providing a sensor to the corresponding fork. Further, a system to which the technique according to the present disclosure is applied is not limited to a depressurization processing system that performs processing on a wafer W under reduced pressure and may be an atmospheric pressure system that performs processing on a wafer W under atmospheric pressure.

The embodiments disclosed herein should be considered to be exemplary in all respects and not restrictive. The above embodiments may be omitted, replaced or modified in various forms without departing from the scope and gist of the appended claims.

1. A system for processing a substrate under a depressurized environment, the system comprising:
a processing chamber configured to perform desired processing on a substrate;
a transfer chamber having a transfer mechanism configured to import or export the substrate into or from the processing chamber; and
a controller configured to control a processing process in the processing chamber,
wherein
the transfer mechanism comprises:
a fork configured to hold the substrate on an upper surface; and
a sensor provided in the fork and configured to measure an internal state of the processing chamber, and
the controller is configured to control the processing process in the processing chamber on the basis of the internal state of the processing chamber measured by the sensor.

2. The system of claim 1, wherein
the processing chamber comprises:
an electrostatic chuck configured to attract and hold the substrate on an upper surface; and
a direct current (DC) power supply configured to apply a DC voltage to the electrostatic chuck,
the sensor is a potential sensor configured to measure a surface potential of the electrostatic chuck, and
the controller controls the amount of DC voltage applied from the DC power supply on the basis of the surface potential of the electrostatic chuck measured by the sensor.

3. The system of claim 2, further comprising an ionizer configured to perform antistatic processing on the surface of the electrostatic chuck.

4. The system of claim 1, wherein
the processing chamber comprises:
an electrostatic chuck configured to attract and hold the substrate on an upper surface;
a heater configured to adjust a surface temperature of the electrostatic chuck; and
a heater power supply configured to control the operation of the heater,
the sensor is a temperature sensor configured to measure the surface temperature of the electrostatic chuck, and
the controller controls the amount of voltage applied from the heater power supply to the heater on the basis of the surface temperature of the electrostatic chuck measured by the sensor.

5. The system of claim 4, wherein
the heater has a plurality of heaters provided in the electrostatic chuck to divide a holding surface of the substrate into a plurality of temperature control regions, and
the sensor measures the surface temperature of the electrostatic chuck for each of the plurality of temperature control regions.

6. The system of claim 1, wherein
the processing chamber comprises:
an electrostatic chuck configured to attract and hold the substrate on an upper surface;
an edge ring disposed to surround a substrate holding area of the electrostatic chuck in a plan view; and
an lifter pin configured to lift the edge ring,
the sensor is a distance sensor configured to measure a height position of an upper surface of the edge ring, and
the controller controls a lifter operation of the edge ring by an operation of the lifter pin on the basis of the height position of the upper surface of the edge ring measured by the sensor.

7. The system of claim 1, wherein
the processing chamber comprises:
an electrostatic chuck configured to attract and hold the substrate on an upper surface;
an edge ring disposed to surround a substrate holding area of the electrostatic chuck in the plan view; and
an edge ring power supply configured to apply a DC voltage to the edge ring,
the sensor is a distance sensor configured to measure a height position of an upper surface of the edge ring, and
the controller controls the amount of DC voltage applied from the edge ring power supply on the basis of the height position of the upper surface of the edge ring measured by the sensor.

8. The system of claim 6, wherein the controller records the amount of consumption of the edge ring on the basis of the height position of the upper surface of the edge ring measured by the sensor and provides a notification about a replacement timing of the edge ring on the basis of the amount of consumption.

9. The system of claim 6, wherein the controller is configured to:
further measure the height position of the upper surface of the electrostatic chuck by the distance sensor; and
calculate a position of the edge ring inside the processing chamber on the basis of a result of measuring the height position of the upper surface and the height position of the upper surface of the edge ring.

10. The system of claim 1, wherein
the sensor is an imaging sensor that detects a reaction product adhering to the inside of the processing chamber after processing the substrate, and
the controller adjusts conditions for the processing process in the processing chamber on the basis of the amount of adhesion of the reaction product measured by the sensor.

11. The system of claim 10, wherein
the processing chamber comprises:
a chamber;
a gas supplier configured to supply a processing gas to the chamber; and
a DC power supply system configured to control plasma generated inside the chamber, and
the controller adjusts the conditions for the processing process by controlling an operation of at least one of the gas supplier or the DC power supply system.

12. The system of claim 10, wherein
the processing chamber configured to perform cleaning processing for removing the reaction product prior to processing the substrate, and
the controller adjusts a period of time in the cleaning processing or a flow rate of a cleaning gas in the cleaning processing on the basis of the amount of adhesion of the reaction product measured by the sensor.

13. The system of claim 1, wherein
the processing chamber comprises:
a chamber;
a plasma generator configured to generate plasma inside the chamber; and
an electromagnet having an excitation circuit and a coil for controlling the uniformity of plasma generated inside the chamber,
the sensor is a magnetic sensor configured to measure a magnetic force distribution of a magnetic field generated by the electromagnet, and
the controller controls a current applied from the excitation circuit to the coil on the basis of the magnetic force distribution measured by the sensor.

14. The system of claim 2, wherein the sensor is at least provided on a lower surface of the fork.

15. The system of claim 10, wherein the sensor is at least provided on an upper surface of the fork.

16. The system of claim 1, wherein
the transfer mechanism has a plurality of forks, and
a different type of sensor is provided for each of the plurality of forks.

17. A method of processing a substrate in a processing system, the processing system including a processing chamber configured to perform desired processing on the substrate under depressurized environment, and a transfer chamber having a transfer mechanism that imports and exports the substrate into and from the processing chamber, wherein the transfer mechanism has a fork configured to hold the substrate on an upper surface and transfer the substrate and a sensor provided in the fork and configured to measure an internal state of the processing chamber, the method comprising:
moving the fork into the processing chamber;
measuring the internal state of the processing chamber by the sensor; and
controlling the processing process in the processing chamber on the basis of a measurement result.

18. The method of claim 17, wherein the transfer mechanism have a plurality of types of sensors and measure a plurality of different types of internal states in the process of measuring the internal state.
